(19) United States
(12) Patent Application Publication
(10) Pub. No.: US 2006/0204761 A1
(43) Pub. Date: Sep. 14, 2006

(54) Cured product of epoxy resin composition and method for producing the same, and photosemiconductor device using the same

(75) Inventor: Hisataka Ito, Ibaraki-shi (JP)

Correspondence Address: SUGHRUE MION, PLLC, 2100 PENNSYLVANIA AVENUE, N.W., SUITE 800, WASHINGTON, DC, 20037, US

(73) Assignee: NITTO DENKO CORPORATION

(21) Appl. No.: 11/364,327

(22) Filed: Mar. 1, 2006

(30) Foreign Application Priority Data
Mar. 1, 2005 (JP) P. 2005-56027

(51) Int. Cl. B32B 27/38; C08L 63/00; C08L 83/00; H01L 21/56; B32B 37/00

(52) U.S. Cl. 428/413; 428/447; 525/476; 438/127

(57) ABSTRACT

An epoxy resin composition for photosemiconductor element encapsulation having small internal stress and excellent light transmissibility is provided. A cured product formed from an epoxy resin composition for photosemiconductor element encapsulation containing the following components (A) to (D). In the above-described cured product, particles of the component (C) silicone resin are homogeneously dispersed, with the particle size being 1 to 100 nm. (A) an epoxy resin, (B) an acid anhydride curing agent, (C) a silicone resin capable of being melt-mixed with the component (A) epoxy resin, and (D) a curing accelerator.

### FIELD OF THE INVENTION

The present invention relates to a cured product of an epoxy resin composition for photosemiconductor element encapsulation, which is excellent in both light transmissibility and low stress property; a method for producing the same; and photosemiconductor device employing the same.

### BACKGROUND OF THE INVENTION

As the resin composition for encapsulation which is used for encapsulating photosemiconductor elements such as light emitting diodes (LED) and the like, a cured product thereof is required to have transparency. In general, epoxy resin compositions obtained by using epoxy resins such as bisphenol A-type epoxy resins, alicyclic epoxy resins or the like, and acid anhydrides as the curing agent, are widely used.

However, when such an epoxy resin composition is used, curing shrinkage which occurs upon curing of the epoxy resin composition generates internal stress, which causes a problem of decrease in the brightness of light emitting elements.

In order to solve these problems, there have been suggested a method of modifying the epoxy resin with a silicone to reduce the elastic modulus, and thus to reduce the internal stress, a method of adding silica fine powder to decrease the linear expansion coefficient of the resin composition for encapsulation, and the like (See Documents 1 and 2).

Document 1: Unexamined published Japanese patent Application JP-A-60-70781

Document 2: Unexamined published Japanese patent Application JP-A-7-25987

### SUMMARY OF THE INVENTION

However, although the method of modifying the epoxy resin with silicone may be able to decrease the elastic modulus, the linear expansion coefficient rather increases, and thus there is a problem that a significant effect on the lowering of stress cannot be obtained totally. Further, in the method of adding silica fine powder, although lowering of the internal stress may be achieved, there occurs a decrease in the light transmittance substantially, and thus the cured product of the resulting resin composition for encapsulation has decreased light transmittance, which is a critical defect for a resin composition for photosemiconductor element encapsulation.

The present invention was accomplished under such circumstances and an object of the present invention is to provide a cured product of epoxy resin composition for photosemiconductor element encapsulation, which has small internal stress and excellent light transmissibility, a method of producing the same, and photosemiconductor devices of high reliability using the same.

The first aspect of the present invention is a cured product of an epoxy resin composition, which is a cured product of an epoxy resin composition for photosemiconductor element encapsulation, said epoxy resin composition comprising the following components (A) to (D):

(A) an epoxy resin, (B) an acid anhydride curing agent, (C) a silicone resin capable of being melt-mixed with the component (A) epoxy resin, and (D) a curing accelerator,

wherein particles of the component (C) silicone resin having a particle size of 1 to 100 nm are homogeneously dispersed in the cured product.

The second aspect of the present invention is a method for producing a cured product of epoxy resin composition for photosemiconductor element encapsulation, which comprises preparing an epoxy resin-silicone resin solution by melt-mixing the above-described component (A) and component (C); preparing a curing agent solution formed by mixing the above-described component (B), component (D) and the other blend components if needed; and mixing the epoxy resin-silicone resin solution and the curing agent solution, filling a mold with the mixed solution, and then curing the mixed solution.

The third aspect of the present invention is a method of producing a cured product of epoxy resin composition for photosemiconductor element encapsulation, which comprises a preparing an epoxy resin composition by heating and mixing the above-described component (A) and component (B), then adding thereto the above-described component (C), component (D) and the other blend components if needed, followed by mixing; and providing the epoxy resin composition in a semi-cured state, putting the epoxy resin composition in the semi-cured state into a predetermined mold, and curing the epoxy resin composition.

The fourth aspect of the present invention is a photosemiconductor device in which a photosemiconductor element is encapsulated with a resin layer for encapsulation comprising the cured product of an epoxy resin composition.

The inventors of the present invention conducted a series of studies in order to obtain a cured product of epoxy resin composition which can simultaneously satisfy the requirements of reduced internal stress and improved light transmissibility. In the process of the studies, they found that silicone resins that are conventionally used to impart low stress property are incompatible with epoxy resins, and thus silicone resin particles aggregate in the resulting cured product and are dispersed in a form of particles having large diameters, thereby leading to a decrease in the light transmissibility. Based on such finding, they carried out further studies to discover that when silicone resin particles having a particle size of 1 to 100 nm are homogeneously dispersed in the cured product, that is, the silicone resin particles are in a so-called nano-dispersed state, a decrease in the light transmissibility does not occur, and a low stress property is imparted by the blended silicone resin, thus both excellent light transmissibility and reduced internal stress being achieved. As a result, the inventors completed the present invention.

Thus, the present invention is a cured product of epoxy resin composition, in which particles of a silicone resin [component (C)] having a particle size of 1 to 100 nm are homogeneously dispersed in a cured product formed by using an epoxy resin composition for photosemiconductor element encapsulation. The silicone resin particles are dispersed in the cured product in a nano-sized form, a decrease in the light transmissibility does not occur, and reduction in the internal stress is realized. Accordingly, the photosemiconductor device in which a photosemiconductor element is encapsulated with the cured product of epoxy resin composition of the present invention has excellent reliability and can satisfactorily perform the function.

Moreover, the cured product of an epoxy resin composition is obtained by preparing an epoxy resin-silicone resin solution, preparing at the same time a curing agent solution, mixing this epoxy resin-silicone resin solution with the curing agent solution, filling this mixed solution in a mold, and then curing the mixed solution. Alternatively, the cured product of epoxy resin composition is obtained by heating and mixing an epoxy resin and an acid anhydride curing agent, then adding thereto a silicone resin, a curing accelerator and if needed the other blend components, and mixing them to prepare an epoxy resin composition, providing the epoxy resin composition in a semi-cured state, then putting the epoxy resin composition in the semi-cured state into a predetermined-mold, and curing the epoxy resin composition. In this way, silicone resin particles may be homogeneously dispersed in the cured product, with the particles having a nano-sized particle size of 1 to 100 nm.

### BRIEF DESCRIPTION OF THE DRAWINGS

By way of example and to make the description more clear, reference is made to the accompanying drawing in which:

FIG. 1 is a scanning electron micrograph (magnification×100 k) of the cross-section of the cured product of epoxy resin composition of Example 3.

FIG. 2 is a scanning electron micrograph (magnification×100 k) of the cross-section of the cured product of epoxy resin composition of Example 6.

FIG. 3 is a scanning electron micrograph (magnification×10 k) of the cross-section of the cured product of epoxy resin composition of Comparative Example 2.

### DETAILED DESCRIPTION OF THE INVENTION

The cured product of epoxy resin composition for photosemiconductor element encapsulation according to the present invention is formed by curing an epoxy resin composition obtained by using an epoxy resin (component A), an acid anhydride curing agent (component B) and a silicone resin (component C), and in the cured product, particles of the silicone resin (component C) are present in a state such that the particles having a particle size of 1 to 100 nm (preferably 5 to 70 nm, more preferably 10 to 50 nm) are homogeneously dispersed. This is the most prominent feature of the present invention. When the particle size of the silicone resin (component C) particles exceeds 100 nm, the light transmissibility may be significantly decreased. According to the present invention, the particle size of the silicone particles may be substantially in the above range and a small number of particles having the particle size outside the above range may exist as long as the effect of the present invention is not prevented.

According to the present invention, the state in which particles of the silicone resin (component C) are homogeneously dispersed in the cured product of epoxy resin composition, with the particle size being 1 to 100 nm, can be confirmed, for example, in the following manner. That is, an epoxy resin composition is prepared, and a cured product is produced using this epoxy resin composition under predetermined curing conditions. Subsequently, the cured product is cut, and the fractured surface is observed with a scanning electron microscope (SEM). Then, from the fractured surface, the dispersed state of the silicone resin (component C) particles is observed, and at the same time the particle size is measured; thereby, it can be confirmed that the particles are homogeneously dispersed substantially with a particle size in the range of 1 to 100 nm. The measurement of the particle size of the silicone resin (component C) particles is carried out by, for example, setting an arbitrary area on the fractured surface of the cured product, and measuring the particle size of the silicone resin (component C) particles within that area. In case a particle has a shape such that the particle size is not uniformly defined, such as in the case of an ellipsoidal shape, instead of a perfect spherical shape, a simple mean value of the largest diameter and the smallest diameter is taken as the particle size of the particle.

Furthermore, it is preferable for the cured product of epoxy resin composition to have a Shore D hardness of 60 or more from the viewpoint of protecting photosemiconductor elements, and a linear expansion coefficient of 100 ppm or less from the viewpoint of reducing the internally occurring stress. The Shore D hardness can be measured using, for example, a Shore D hardness tester. The linear expansion coefficient can be determined by, for example, measuring the glass transition temperature using a thermomechanical analyzer (TMA) and calculating the linear expansion coefficient from the glass transition temperature.

The epoxy resin (component A) is not particularly limited, and a variety of conventionally known epoxy resins, for example, bisphenol A type epoxy resins, bisphenol F type epoxy resins, novolac type epoxy resins such as phenol novolac type epoxy resins or cresol novolac type epoxy resins, alicyclic epoxy resins, nitrogen-containing cyclic epoxy resins such as triglycidyl isocyanurates and hydantoin epoxy resins, hydrogenated bisphenol A type epoxy resins, aliphatic epoxy resins, glycidyl ether type epoxy resins, bisphenol S type epoxy resins, biphenyl type epoxy resins which constitute the main stream of low water-absorption products, dicyclo ring type epoxy resins, naphthalene type epoxy resins and the like may be mentioned. These can be used individually or in combination of two or more species. Among these epoxy resins, a triglycidyl isocyanurate represented by the following structural formula (a) and an alicyclic epoxy resin represented by the following structural formula (b) are preferably used, in view of their excellent transparency, resistance to discoloration, and melt miscibility with silicone resins (component C):

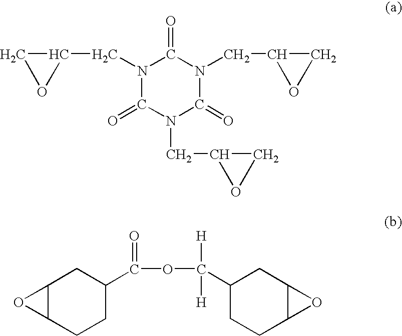

The epoxy resin (component A) may be solid or liquid at ambient temperature. The average epoxy equivalent of the epoxy resin used is preferably 90 to 1000, and the softening point in the case of the epoxy resin being solid is preferably 160° C. or lower. When the epoxy equivalent is less than 90, the cured product of epoxy resin composition for photosemiconductor element encapsulation may become brittle. On the other hand, when the epoxy equivalent exceeds 1000, the glass transition temperature (Tg) of the cured product may be lowered. According to the present invention, the term ambient temperature is used to refer to a temperature in the range of 5 to 35° C.

Examples of the acid anhydride curing agent (component B) that is used together with the epoxy resin (component A) include phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, methylhexahydrophthalic anhydride, methyltetrahydrophthalic anhydride, and the like. These may be used individually or in combination of two or more species. Among these acid anhydride curing agents, phthalic anhydride, hexahydrophthalic anhydride, tetrahydrophthalic anhydride, or methylhexahydrophthalic anhydride is preferably used. The acid anhydride curing agent preferably has a molecular weight of about 140 to 200, and an acid anhydride which is colorless or pale yellow colored is preferably used.

The mixing ratio of the epoxy resin (component A) and the acid anhydride curing product (component B) is preferably set to a ratio such that 0.5 to 1.5 equivalents, more preferably 0.7 to 1.2 equivalents, of the active group in the acid anhydride curing agent (component B) (an acid anhydride group or a hydroxyl group in the case of the following phenol resin), which is capable of reacting with the epoxy group, is used with respect to 1 equivalent of the epoxy group in the epoxy resin (component A) . When less than 0.5 equivalents of the active group are used, there is a tendency that the curing rate of the epoxy resin composition for photosemiconductor element encapsulation may be reduced, and at the same time, the glass transition temperature (Tg) of the cured product may be lowered. When more than 1.5 equivalents are used, there is a tendency that moisture resistance decreases.

Furthermore, in addition to the acid anhydride curing product (component B), conventionally known curing agents for epoxy resin, for example, phenolic resin-based curing agents, amine-based curing agents, the products of partial esterification of the aforementioned acid anhydride curing agents with alcohol, or carboxylic acid curing agents such as hexahydrophthalic acid, tetrahydrophthalic acid, methylhexahydrophthalic acid and the like, may be used in combination with the acid anhydride curing agent, in accordance with the purpose and application. For example, when a carboxylic acid curing agent is used in combination, the curing rate can be increased, and thus productivity can be improved. When these curing agents are used, the mixing ratio may be similar to the mixing ratio (equivalent ratio) for the case where the acid anhydride curing agent is used.

The silicone resin (component C) that is used together with the component A and component B is not particularly limited as long as it is capable of being melt-mixed with the epoxy resin (component A), and various polyorganosiloxanes may be used such that solid polyorganosiloxane is used in the absence of solvent, or liquid polyorganosiloxane at ambient temperature may be used. As such, the silicone resin (component C) used according to the present invention is advantageously dispersible in the cured product of epoxy resin composition, homogeneously in a nano-sized scale. For such silicone resin (component C), mention may be made of, for example, a compound having a constituent siloxane unit represented by the following general formula (1). The compound also has at least one hydroxyl group or alkoxy group is bound to a silicon atom per molecule, and among the monovalent hydrocarbon groups (R) bound to silicon atoms, substituted or unsubstituted aromatic hydrocarbon groups occupy 10% by mole or greater.
Rₘ(OR¹)ₙSiO_{(4-m-n)/2} (1)

wherein R is a substituted or unsubstituted, saturated monovalent hydrocarbon group having 1 to 18 carbon atoms or aromatic hydrocarbon group having 6 o 18 carbon atoms, and a plurality of R may be the same or different; R¹ is a hydrogen atom or an alkyl group having 1 to 6 carbon atoms, and a plurality of R¹ may be the same or different; and m and n are each an integer from 0 to 3.

In the formula (1), for the substituted or unsubstituted, saturated monovalent hydrocarbon group R having 1 to 18 carbon atoms, specific examples of the unsubstituted, saturated monovalent hydrocarbon group include straight-chained or branched alkyl groups such as a methyl group, an ethyl group, a propyl group, an isopropyl group, an n-butyl group, an isobutyl group, a t-butyl group, a pentyl group, an isopentyl group, a hexyl group, an isohexyl group, a heptyl group, an isoheptyl group, an octyl group, an isooctyl group, a nonyl group, a decyl group and the like; cycloalkyl groups such as a cyclopentyl group, a cyclohexyl group, a cyclooctyl group, a bicyclo[2,2,1]heptyl group, a decahydronaphthyl group and the like; aromatic groups such as an aryl group, such as a phenyl group, a naphthyl group, a tetrahydronaphthyl group, a tolyl group, an ethylphenyl group and the like, and an aralkyl group, such as a benzyl group, a phenylethyl group, a phenylpropyl group, a methylbenzyl group and the like; and the like.

Meanwhile, for R in the above formula (1), the substituted, saturated monovalent hydrocarbon group may be exemplified by those having part or all of the hydrogen atoms in the hydrocarbon group substituted with halogen atoms, cyano groups, amino groups, epoxy groups or the like, and specific examples thereof include substituted hydrocarbon groups such as a chloromethyl group, a 2-bromoethyl group, a 3,3,3-trifluoropropyl group, a 3-chloropropyl group, a chlorophenyl group, a dibromophenyl group, a difluorophenyl group, a β-cyanoethyl group, a γ-cyanopropyl group and a β-cyanopropyl group, and the like.

Preferred ones for R in the above formula (1) are an alkyl group or an aryl group from the viewpoints of compatibility with the epoxy resin, and the properties of the resulting epoxy resin composition. For the alkyl group, more preferred examples include alkyl groups having 1 to 3 carbon atoms, and particularly preferred is a methyl group. For the aryl group, particularly preferred is a phenyl group. These groups selected for R in the above formula (1) may be identical or different among the same siloxane unit, or among different siloxane units.

For the silicone resin (component C), it is preferable that, for example, in the structure represented by the above formula (1), 10% by mole or greater of the monovalent hydrocarbon groups (R) bound to silicon atoms are selected from aromatic hydrocarbon groups. At the rate of less than 10% by mole, the compatibility with the epoxy resin may be insufficient, and thus the silicone resin dissolved or dispersed in the epoxy resin may turn the epoxy resin opaque. Also, the cured product of the resulting resin composition shows a tendency that sufficient effects cannot be obtained in the resistance to photodegradation and physical properties. The content of the aromatic hydrocarbon group as such is more preferably 30% by mole or greater, and particularly preferably 40% by mole or greater. The upper limit for the content of the aromatic hydrocarbon group is 100% by mole.

The group (OR¹ ) in the above formula (1) is a hydroxyl group or an alkoxy group, and R¹ in the case where (OR¹) is an alkoxy group may be exemplified by the alkyl groups having 1 to 6 carbon atoms among the alkyl groups listed specifically for the above-described R. More specifically, R¹ may be exemplified by a methyl group, an ethyl group, or an isopropyl group. These groups may be identical or different among the same siloxane unit, or among different siloxane units.

The silicone resin (component C) preferably has at least one hydroxyl group or alkoxy group that is bound to a silicon atom per molecule, that is, an (OR¹) group of formula (1) in at least one siloxane unit constituting the silicone resin. When the silicone resin does not have the hydroxyl group or alkoxy group, the compatibility with the epoxy resin may be insufficient, and it may be difficult to obtain satisfactory physical properties in the cured product formed by the resulting resin composition, for a reason that is believed to be that, although the exact mechanism is not clear, these hydroxyl groups or alkoxy groups exert an effect in a certain manner in the curing reaction of the epoxy resin. With respect to the silicone resin (component C), the amount of the hydroxyl group or alkoxy group bound to silicon atom is preferably set to the range of 0.1 to 15% by weight, more preferably 1 to 10% by weight, in terms of the OH group. When the amount of the hydroxyl group or alkoxy group is outside the above-mentioned range, the compatibility with the epoxy resin (component A) may decrease, and in particular, when the amount exceeds 15% by weight, there is a possibility that the hydroxyl group or alkoxy group causes autodehydration or dealcoholation.

In the above formula (1), the repeating numbers m and n are each an integer from 0 to 3. The values that can be taken by the repeating numbers m and n may vary for different siloxane units, and in explaining the siloxane unit constituting the particular silicone resin in more detail, mention may be made of the units A1 through A4 represented by the following general formulas (2) through (5).
Unit A1: (R)₃SiO_{1/2} (2)
Unit A2: (R)₂(OR¹)ₙSIO_{(2-n)/2} (3)

wherein n is 0 or 1.
Unit A3: (R) (OR¹)ₙSiO_{(3-n)/2} (4)

wherein n is 0, 1 or 2.
Unit A4: (OR¹)ₙSiO_{(4-n)/2} (5)

wherein n is an integer from 0 to 3.

In the formulas (2) through (5), R is a substituted or unsubstituted, saturated monovalent hydrocarbon group having 1 to 18 carbon atoms or aromatic-hydrocarbon group having 6to 18 carbon atoms, and a plurality of R may be the same or different; and R¹ is a hydrogen atom or an alkyl group having 1 to 6 carbon atoms, and a plurality of R¹ may be the same or different.

Thus, for m in the above formula (1), the case where m=3 corresponds to the unit A1 represented by the above formula (2); the case where m=2 to the unit A2 represented by the above formula (3); the case where m=1 to the unit A3 represented by the above formula (4); and the case where m=0 to the unit A4 represented by the above formula (5). Among these, the unit A1 represented by the above formula (2) is a structural unit having only one siloxane bond and constituting the terminal group, while the unit A2 represented by the above formula (3) is a structural unit having two siloxane bonds when n is 0, and constituting a siloxane bonding in a linear form. In the case where n is 0 with respect to the unit A3 represented by the above formula (4), and in the case where n is 0 or 1 with respect to the unit A4 represented by the above formula (5), the units are structural units possibly having 3 or 4 siloxane bonds and contributing the branched structure or crosslinked structure.

For the particular silicone resin (component C), the respective constitutional ratios for the units A1 through A4 respectively represented by the above formulas (2) through (5) are preferably set to the following ratios (a) through (d).

(a) 0 to 30% by mole of unit A1,

(b) 0 to 80% by mole of unit A2,

(c) 20 to 100% by mole of unit A3, and

(d) 0 to 30% by mole of unit A4.

More preferably, unit A1 and unit A4 are contained in an amount of 0% by mole, unit A2 in an amount of 0 to 70% by mole, and unit A3 in an amount of 30 to 100% by mole. That is, when the respective constitutional ratios for the units A1 through A4 are set to the above-mentioned ranges, effects of imparting (maintaining) appropriate hardness or elastic modulus to the cured product can be obtained, which are further desirable.

The silicone resin (component C) has the respective constituent units bound to each other or in a row, and the degree of polymerization of the siloxane units is preferably in the range of 6 to 10,000. The nature of the silicone resin (component C) may vary depending on the degree of polymerization and the degree of crosslinking, and may be either in the liquid phase or in the solid phase.

The silicone resin (component C) represented by formula (1) as such can be produced by known methods. For example, the silicone resin is obtained through a reaction such as hydrolyzing at least one of organosilanes and organosiloxanes in the presence of a solvent such as toluene or the like. In particular, a method of subjecting an organochlorosilane or an organoalkoxysilane to hydrolytic condensation is generally used. Here, the organo group is a group corresponding to R in the above formula (1), such as an alkyl group, an aryl group or the like. The units A1 through A4 respectively represented by the above formulas (2) through (5) are correlated with the structure of the silanes used as the respective starting materials. For example, in the case of chlorosilane, when a triorganochlorosilane is used, the unit A1 represented by formula (2) can be obtained; when a diorganodichlorosilane is used, the unit A2 represented by formula (3) can be obtained; when an organotrichlorosilane is used, the unit A3 represented by formula (4) can be used; and when tetrachlorosilane is used, the unit A4 represented by formula (5) can be used. In addition, the substituent of silicon atom represented by (OR¹) with respect to the above formulas (1) and (3) through (5) is an uncondensed residual group of hydrolysis.

When the silicone resin (component C) is solid at ambient temperature, the softening point (flow point) is preferably 150° C. or lower, and particularly preferably 120° C. or lower, from the viewpoint of melt mixing with the epoxy resin composition.

The content of the silicone resin (component C) is preferably set to the range of 5 to 60% by weight of the total epoxy resin composition. Particularly preferably, the content is in the range of 10 to 40% by weight, in view of the linear expansion coefficient increasing. When the content is less than 5% by weight, there is a tendency that the heat resistance and light resistance are decreased. When the content is more than 60% by weight, there is a tendency that the cured product of the obtained resin composition becomes remarkably brittle.

The epoxy resin composition for photosemiconductor element encapsulation of the present invention may suitably contain, in addition to the epoxy resin (component A), acid anhydride curing agent (component B) and silicone resin (component C), various known additives that are conventionally used, such as a curing accelerator, a deterioration preventing agent, a modifying agent, a silane coupling agent, a defoaming agent, a leveling agent, a release agent, dyes, pigments and the like, if desired.

The curing accelerator is not particularly limited, and may be exemplified by tertiary amines such as 1,8-diazabicyclo (5.4.0)undecene-7, triethylenediamine, tri-2,4,6-dimethylaminomethylphenol and the like; imidazoles such as 2-ethyl-4-methylimidazole, 2-methylimidazole and the like; phosphorus compounds such as triphenylphosphine, tetraphenylphosphonium-tetraphenylborate, tetra-n-butylphosphonium-o, o-diethylphosphorodithioate and the like; quaternary ammonium salts; organic metal salts; and derivatives thereof and the like. These may be used individually or in combination of two or more species. Among these curing accelerators, tertiary amines, imidazoles and phosphorus compounds are preferably used.

The content of the curing accelerator is preferably set to 0.01 to 8.0 parts by weight, and more preferably 0.1 to 3.0 parts by weight, relative to 100 parts by weight (hereinafter, abbreviated to “parts”) of the epoxy resin (component A). When the content is less than 0.01 parts, it is difficult to obtain a sufficient curing accelerating effect. When the content exceeds 8.0 parts, the resulting cured product may exhibit discoloration.

The deterioration preventing agent may be exemplified by conventionally known degradation preventing agents such as phenol compounds, amine compounds, organic sulfur compounds, phosphine compounds and the like. The modifying agent may be exemplified by conventionally known modifying agents such as glycols, silicones, alcohols and the like. The silane coupling agent may be exemplified by conventionally known silane coupling agents such as silanes, titanates and the like. The defoaming agent may be exemplified by conventionally known defoaming agents such as silicones and the like.

The epoxy resin composition for photosemiconductor element encapsulation can be prepared, for example, in the following manner, and can be obtained in the form of liquid, powder or a tablet produced from the powder. That is, in order to obtain a liquid epoxy resin composition, for example, the above-described components, including the epoxy resin (component A), the acid anhydride curing agent (component B) and the particular silicone resin (component C), as well as various additives that are blended in as necessary, may be appropriately blended. In order to obtain the epoxy resin composition in the form of powder or a tablet produced from the powder, the epoxy resin composition can be prepared by, for example, appropriately blending the above-described components, preliminarily mixing the components, then kneading and melt mixing the resulting mixture using a kneading machine, subsequently cooling the resulting mixture to room temperature, and then pulverizing the cooled product by a known means, and if necessary, tabletting the pulverization product.

The epoxy resin composition for photosemiconductor element encapsulation thus obtained is used for encapsulating photosemiconductor elements such as LED (Light Emitting Diode), charge-coupled sensor device (CCD) or the like. That is, encapsulation of a photosemiconductor element using the epoxy resin composition for photosemiconductor element encapsulation is not particularly limited in the method, and can be carried out by a known molding method such as conventional transfer molding, casting or the like. When the epoxy resin composition is liquid, it is favorable to use the epoxy resin composition as the so-called two-liquid type such that at least the epoxy resin component and the acid anhydride curing agent component are stored separately and mixed immediately before use. When the epoxy resin composition is in the form of powder or tablet after being subjected to a predetermined aging process, the above-mentioned components are provided in the state of B stage (semi-cured state) upon melting mixing of the components, and this may be heated and melted upon use.

To describe in more detail, the cured product of epoxy resin composition is obtained by preparing two liquids in advance, such that an epoxy resin-silicone resin solution is prepared by melt mixing the epoxy resin (component A) and the silicone resin (component C), and at the same time, a curing agent solution is formed by mixing the acid anhydride curing agent (component B), the curing accelerator (component D) and if needed the other blend components. Next, the epoxy resin-silicone resin solution and the curing agent solution are mixed immediately before use, this mixed solution is filled in a mold, and this mixed solution is cured under predetermined conditions.

Alternatively, the cured product of epoxy resin composition is obtained by preparing an epoxy resin composition by heating and mixing the epoxy resin (component A) and the acid anhydride curing agent (component B), then adding thereto the silicone resin (component C), the curing accelerator (component D) and the other remaining components, and mixing. Subsequently, the epoxy resin composition is provided in a semi-cured state, appropriately pulverized and further tabletted to form a tablet product. This tablet product is cured by transfer molding.

When the cured product of epoxy resin composition of the present invention is observed, for example, at its fractured surface with a scanning electron microscope (SEM), as described above, it can be confirmed that the particles formed by melt mixing the epoxy resin (component A) with the silicone resin (component C) are homogeneously dispersed, with the particle size being substantially 1 to 100 nm. As such, when the silicone resin is homogeneously dispersed in a nano-sized scale, the silicone resin does not cause lowering of the light transmissibility and induces an improvement in the low stress property while cured product keeps low thermal expansion coefficient.

In addition, when photosemiconductor elements are encapsulated with such cured product of epoxy resin composition, lowering of the internal stress may be induced, and degradation of the photosemiconductor elements in making them moisture resistant may be effectively prevented. Thus, the photosemiconductor device of the present invention in which the photosemiconductor element is encapsulated with the cured product of epoxy resin composition of the present invention, has excellent reliability and low stress property, and can sufficiently perform the function.

### EXAMPLES

Next, the present invention will be described with reference to Examples and Comparative Examples.

First, the following components were provided.

[Epoxy Resin a]

Triglycidyl isocyanurate represented by the following structural formula (a) (epoxy equivalent 100)

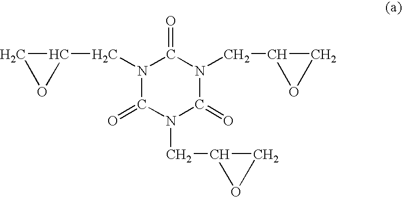

[Epoxy Resin b]

Alicyclic epoxy resin represented by the following structural formula (b) (epoxy equivalent 134)

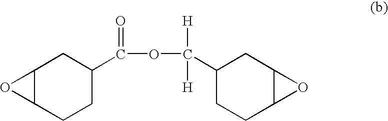

[Acid Anhydride Curing Agent]

Mixture of 4-methylhexahydrophthalic anhydride (x) and hexahydrophthalic anhydride (y) (mixing weight ratio x:y=7:3) (acid anhydride equivalent 168)

[Silicone Resin a]

A mixture containing 148.2 g (66 mol %) of phenyltrichlorosilane, 38.1 g (24 mol %) of methyltrichlorosilane, 13.7 g (10 mol %) of dimethyldichlorosilane and 215 g of toluene was added dropwise to a mixed solvent containing 550 g of water, 150 g of methanol and 150 g of toluene that had been placed in a flask in advance, over 5 minutes with vigorous agitation. The temperature in the flask was elevated to 75° C., and agitation was continued for 10 more minutes. This solution was left to stand, cooled to room temperature (25° C). Then, the separated aqueous layer was removed, subsequently water was mixed, and the mixture was agitated and left to stand. The operation of washing with water to remove the aqueous layer was carried out until the washed water layer became neutral. The remaining organic layer was subjected to reflux for 30 minutes, and water and a part of toluene were distilled off. The obtained toluene solution of organosiloxane was filtered to remove any impurities, and then the residual toluene was distilled off under reduced pressure using a rotary evaporator, thus to obtain a solid silicone resin a. The obtained silicone resin a contained 6% by weight of OH group. The starting material chlorosilane used was all reacted, and the obtained silicone resin a consisted of 10 mol % of the unit A2 and 90 mol % of the unit A3, also having 60% of phenyl group and 40% of methyl group.

[Silicone Resin b]

A mixture containing 200 g (100 mol %) of phenyltrichlorosilane and 215 g of toluene was added dropwise to a mixed solvent containing 550 g of water, 150 g of methanol and 150 g of toluene that had been placed in a flask in advance, over 5 minutes with vigorous agitation. The temperature in the flask was elevated to 75° C., and agitation was continued for 10 more minutes. This solution was left to stand, cooled to room temperature (25° C.). Then, the separated aqueous layer was removed, subsequently water was added, and the mixture was agitated and left to stand. The operation of washing with water to remove the aqueous layer was carried out until the washed water layer became neutral. The remaining organic layer was subjected to reflux for 30 minutes, and water and a part of toluene were distilled off. The obtained toluene solution of organosiloxane was filtered to remove any impurities, and then the residual toluene was distilled off under reduced pressure using a rotary evaporator, thus to obtain a solid silicone resin b. The obtained silicone resin b contained 6% by weight of OH group. The starting material chlorosilane used was all reacted, and the obtained silicone resin b consisted of 100 mol % of the unit A3, also having 100% of phenyl group.

[Silicone Resin c]

206 g (50 mol %) of phenyltrimethoxysilane and 126 g (50 mol %) of dimethyldimethoxysilane were introduced into a flask, and a mixture containing 1.2 g of a 20% aqueous HCl solution and 40 g of water was added dropwise thereto. After completion of dropwise addition, the mixture was subjected to reflux for 1 hour. Subsequently, the resulting solution was cooled to room temperature (25° C.), and then the solution was neutralized with sodium hydrogen carbonate. The obtained organosiloxane solution was filtered to remove any impurities, and then low boiling point substances were distilled off under reduced pressure using a rotary evaporator, thus to obtain a liquid silicone resin c. The resulting silicone resin c contained 9% by weight of hydroxyl group and alkoxy group, as calculated in terms of OH group. The obtained silicone resin c consisted of 50 mol % of the unit A2 and 50 mol % of the unit A3, further having 33% of phenyl group and 67% of methyl group.

[Silicone Resin d]

A mixture containing 182.5 g (90 mol %) of methyltrichlorosilane, 17.5 g (10 mol %) of dimethyldichlorosilane and 215 g of toluene was added dropwise to a mixed solvent containing 550 g of water, 150 g of methanol and 150 g of toluene that had been placed in a flask in advance, over 5 minutes with vigorous agitation. The temperature in the flask was elevated to 75° C., and agitation was continued for 10 more minutes. This solution was left to stand, cooled to room temperature (25° C.). Then, the separated aqueous layer was removed, subsequently water was mixed, and the mixture was agitated and left to stand. The operation of washing with water to remove the aqueous layer was carried out until the toluene layer became neutral. The remaining organic layer was subjected to reflux for 30 minutes, and water and a part of toluene were distilled off. The obtained toluene solution of organosiloxane was filtered to remove any impurities, and then the residual toluene was distilled off under reduced pressure using a rotary evaporator, thus to obtain a solid silicone resin d. The resulting silicone resin d contained 6% by weight of OH group. The starting material chlorosilarie used was all reacted, and the obtained silicone resin d consisted of 10 mol % of the unit A2 and 90 mol % of the unit A3, also having 100% of methyl group.

[Curing Accelerator]

Tetra-n-butylphosphonium-o,o-diethylphosphorodithioate

[Modifying Agent]

Propylene glycol

[Deterioration Preventing Agent]

9,10-Dihydro-9-oxa-10-phosphaphenanthrene-10-oxide

### Examples 1 Through 8, and Comparative Examples 1 Through 3

The components indicated in the following Table 1 and Table 2 were blended at the ratios indicated in the tables, and epoxy resin compositions were prepared according to any one method described below.

### Liquid Casting: Examples 4 and 6, and Comparative Example 3

Liquid A was prepared by heating and melting the liquid epoxy resin at 80 to 100° C., melt mixing the epoxy resin with the silicone resin for 30 to 60 minutes, and then cooling the resulting mixture to room temperature. Meanwhile, Liquid B was prepared by mixing the acid anhydride curing agent with various additives at 70 to 100° C., and adding the curing accelerator thereto at 50 to 70° C. Subsequently, Liquid A and Liquid B were mixed at room temperature immediately before producing a specimen by casting.

### Transfer Molding: Examples 1 to 3, 5, 7 and 8, Comparative Examples 1 and 2

First, the epoxy resin and the acid anhydride curing agent were heated and mixed at a temperature above the melting point (for example, 120° C.), the resulting mixture was melt mixed with the silicone resin at 100 to 120 C., and then the curing accelerator and other additives were added thereto. Subsequently, the resulting mixture was aged at mild temperature (40 to 50° C.) to obtain an epoxy resin composition in the state of B stage. This epoxy resin composition was appropriately pulverized and tabletted to produce an epoxy resin composition tablet.

TABLE 1
(Parts by weight)

| | | Example | | | | | | | |
|---|---|---|---|---|---|---|---|---|---|
| | | 1 | 2 | 3 | 4 | 5 | 6 | 7 | 8 |
| Epoxy | a | 100 | 100 | 100 | — | 100 | — | 100 | 100 |
| compound | b | — | — | — | 100 | | 100 | — | — |
| Acid anhydride | | 168 | 168 | 168 | 120 | 168 | 120 | 168 | 168 |
| curing agent | | | | | | | | | |
| Silicone | a | 30 | 110 | 400 | 90 | — | — | 15 | 180 |
| resin | b | — | — | — | — | 110 | — | — | — |
| | c | — | — | — | — | — | 90 | — | — |
| | d | — | — | — | — | — | — | — | — |

| | | | | | | | | |
|---|---|---|---|---|---|---|---|---|
| Deterioration | 1 | 1 | 1 | 1 | 1 | 1 | 1 | 1 |
| preventing | | | | | | | | |
| agent | | | | | | | | |
| Modifying | 10 | 10 | 10 | 10 | 10 | 10 | 10 | 10 |
| agent | | | | | | | | |
| Curing | 1 | 1 | 1 | 1 | 1 | 1 | 1 | 1 |
| accelerator | | | | | | | | |
| Content of | 10 | 30 | 60 | 30 | 30 | 30 | 5 | 40 |
| silicone | | | | | | | | |
| resin (wt %) | | | | | | | | |

TABLE 2
(Parts by weight)

| | | Comparative | | |
|---|---|---|---|---|
| | | Example | | |
| | | 1 | 2 | 3 |
| Epoxy compound | a | 100 | 100 | — |
| | b | — | — | 100 |
| Acid anhydride curing agent | | 168 | 168 | 120 |
| Silicone resin | a | — | — | — |
| | b | — | — | — |
| | c | — | — | — |
| | d | — | 110 | 90 |

| | | | |
|---|---|---|---|
| Deterioration preventing agent | 1 | 1 | 1 |
| Modifying agent | 10 | 10 | 10 |
| Curing accelerator | 1 | 1 | 1 |
| Content of silicone resin (wt %) | — | 30 | 30 |

Using each of the epoxy resin compositions thus obtained, the cross-section of the cured product was observed, and glass transition temperature, linear expansion coefficient, light transmittance, flexural modulus, flexural strength, and hardness were respectively measured and evaluated according to the following methods. The results are shown in the following Table 3 through Table 5.

[Observation of Cross-Section of Cured Product]

Using each of the epoxy resin compositions, a specimen was produced as follows. In the liquid casting method, Liquid A and Liquid B were mixed at room temperature, and the mixture was degassed by using a pressure reducing apparatus, before casting. Subsequently, the mixture was filled into a mold, and a specimen was produced under the curing conditions of 120° C. ×1 hour and 150° C. ×3 hours. Meanwhile, in the transfer molding method, the tablet product of the epoxy resin composition was used to produce a specimen by transfer molding (curing conditions: 150° C. ×4 minutes+150° C. ×5 hours).

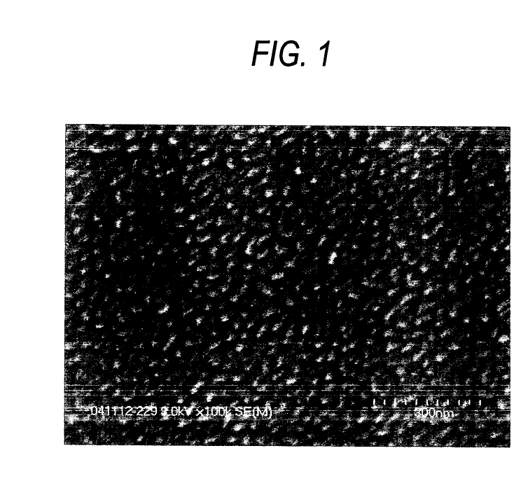

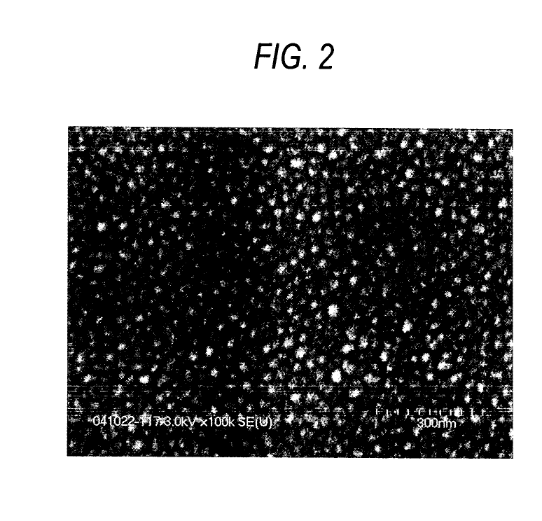

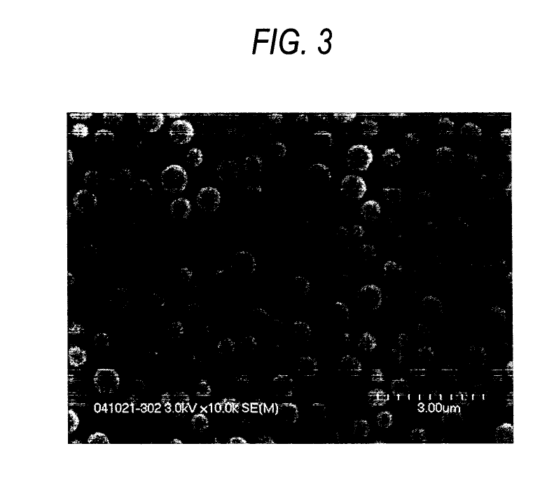

The specimen thus produced was cut and subjected to ion polishing (6 kV×6 hours) to obtain a cross-section. The cross-section was fixed on a previously arranged sample holder, was subjected to Pt-Pd sputtering, and was observed with a scanning electron microscope (Hitachi, Ltd., S-4700 FE-SEM) (accelerating voltage: 3 kV, magnification 10k to 100k). FIG. 1 shows the scanning electron micrograph (magnification×100k) of the cross-section of the cured product formed by using the epoxy resin composition of Example 3. FIG. 2 shows the scanning electron micrograph (magnification×100 k) of the cross-section of the cured product formed by using the epoxy resin composition of Example 6. FIG. 3 shows the scanning electron micrograph (magnification×10k) of the cross-section of the cured product formed by using the epoxy resin composition of Comparative Example 2. As a result, the state in which particles of the silicone resin were homogeneously dispersed in the system in a nano-sized scale (the particle size of the silicone resin particles being in the range of 1 to 100 nm) was indicated as “nano-dispersed”; the state in which no silicone resin was used was indicated as “-”; and the state in which the compatibility of the silicone resin with the epoxy resin was poor, and the particles were not dispersed in the system in a nano-sized scale (1 to 100 nm) was indicated as “incompatible”.

[Glass Transition Temperature, Linear Expansion Coefficient]

Each of the epoxy resin composition was used to produce a specimen (20 mm×5 mm×thickness 5 mm) as described above. Using the specimen (cured product), the glass transition temperature was measured with a thermal analyzer (TMA, Shimadzu Corporation, TMA-50) at a temperature increasing rate of 2° C. /min. For the linear expansion coefficient, the linear expansion coefficient at a temperature range lower than the glass transition temperature was calculated from above-described TMA measurement.

[Light Transmittance]

Each of the epoxy resin compositions was used to produce a specimen (thickness 1 mm) as described above, and the light transmittance was measured by immersing the cured product in fluid paraffin. The light transmittance at a wavelength of 450 nm was measured at room temperature (25° C.) using a spectrophotometer UV3101 manufactured by Shimadzu Corporation.

[Flexural Modulus, Flexural Strength]

Each of the epoxy resin compositions was used to produce a specimen (100 mm×10 mm×thickness 5 mm) as described above, and this specimen (cured product) was used to measure the flexural modulus and the flexural strength at ambient temperature (25° C.) with an autograph (Shimadzu Corporation, AG500C) at a head speed of 5 mm/min.

[Hardness]

Each of the epoxy resin compositions was used to produce a specimen (thickness 1 mm) as described above, and this specimen was used to measure the hardness at room temperature (25° C.) with a Shore D hardness meter (Ueshima Seisakusho Co., Ltd.).

TABLE 3

| | Example | | | | | |
|---|---|---|---|---|---|---|
| | 1 | 2 | 3 | 4 | 5 | 6 |
| Cross-section of | Nano- | Nano- | Nano- | Nano- | Nano- | Nano- |
| cured product | dispersed | dispersed | dispersed | dispersed | dispersed | dispersed |
| observed | | | | | | |
| Glass transition | 152 | 145 | 130 | 145 | 155 | 140 |
| temperature (° C.) | | | | | | |
| Linear expansion | 66 | 73 | 88 | 70 | 73 | 92 |
| coefficient | | | | | | |
| (ppm/° C.) | | | | | | |
| Light | 94 | 92 | 92 | 93 | 93 | 94 |
| transmittance | | | | | | |
| (%) | | | | | | |
| Flexural modulus | 2680 | 2650 | 2430 | 2500 | 2640 | 2900 |
| (N/mm²) | | | | | | |
| Flexural Strength | 97 | 81 | 71 | 91 | 94 | 70 |
| (N/mm²) | | | | | | |
| Hardness (Shore | 80 | 80 | 78 | 78 | 80 | 80 |
| D) | | | | | | |

TABLE 4

Example

| | 7 | 8 |
|---|---|---|
| Cross-section of cured | Nano-dispersed | Nano-dispersed |
| product observed | | |
| Glass transition temperature | 178 | 146 |
| (° C.) | | |
| Linear expansion coefficient | 62 | 84 |
| (ppm/° C.) | | |
| Light transmittance (%) | 95 | 92 |
| Flexural modulus (N/mm²) | 2800 | 2510 |
| Flexural Strength (N/mm²) | 107 | 80 |
| Hardness (Shore D) | 80 | 79 |

TABLE 5

| | Comparative | | |
|---|---|---|---|
| | Example | | |
| | 1 | 2 | 3 |
| Cross-section of | — | Incompatible | Incompatible |
| cured product | | | |
| observed | | | |
| Glass transition | 180 | 139 | 155 |
| temperature (° C.) | | | |
| Linear expansion | 67 | 110 | 107 |
| coefficient (ppm/° C.) | | | |
| Light transmittance | 94 | 38 | 28 |
| (%) | | | |
| Flexural modulus | 3010 | 2850 | 2910 |
| (N/mm²) | | | |
| Flexural Strength | 102 | 40 | 60 |
| (N/mm²) | | | |
| Hardness (Shore D) | 82 | 67 | 77 |

From the above results, it was confirmed from the observation of the cross-sections of the cured products of Examples that the silicone resin was homogeneously nano-dispersed with a particle size of 1 to 100 nm. It was also found that the cured products had high light transmittance, low flexural modulus due to suppressed increase in the linear expansion coefficient, and excellent low stress property. In contrast, the product of Comparative Example 1 had high flexural modulus and high glass transition temperature. For the products of Comparative Examples 2 and 3 the observation of the cross-section of the cured products showed that the silicone resin was not compatible and aggregated to form an incompatible system, not like the products of Examples, and thus the light transmittance was low. Furthermore, lowering of the flexural modulus was not obvious, and the decrease in the flexural strength and the change in the linear expansion coefficient were both large.

While the invention has been described in detail and with reference to specific embodiments thereof, it will be apparent to one skilled in the art that various changes and modifications can be made therein without departing from the scope thereof.

This application is based on Japanese patent application No. 2005-56027 filed Mar. 1, 2005, the entire contents thereof being hereby incorporated by reference.

What is claimed is:

1. A cured product of an epoxy resin composition for photosemiconductor element encapsulation, said epoxy resin composition comprising the following components (A) to (D):
(A) an epoxy resin,
(B) an acid anhydride curing agent,
(C) a silicone resin capable of being melt-mixed with the component (A) epoxy resin, and
(D) a curing accelerator,
wherein particles of the component (C) silicone resin having a particle size of 1 to 100 nm are homogenously dispersed in the cured product.

2. A method for producing a cured product of an epoxy resin composition for photosemiconductor element encapsulation, comprising
preparing an epoxy resin-silicone resin solution by melt-mixing the following component (A) and component (C);
preparing a curing agent solution formed by mixing the following component (B), component (D) and the remaining blend components; and
mixing the epoxy resin-silicone resin solution and the curing agent solution,
filling a mold with the mixed solution, and
curing the mixed solution:
(A) an epoxy resin,
(B) an acid anhydride curing agent,
(C) a silicone resin capable of being melt-mixed with the component (A) epoxy resin, and
(D) a curing accelerator.

3. A method for producing a cured product of an epoxy resin composition for photosemiconductor element encapsulation, comprising
preparing an epoxy resin composition by heating and mixing the following component (A) and component (B),
adding thereto the following component (C), component (D) and the remaining blend components, and mixing; and
providing the epoxy resin composition in a semi-cured state,
putting the epoxy resin composition in the semi-cured state into a predetermined mold, and
curing the epoxy resin composition:
(A) an epoxy resin,
(B) an acid anhydride curing agent,
(C) a silicone resin capable of being melt-mixed with the component (A) epoxy resin, and
(D) a curing accelerator.

4. A photosemiconductor device, in which a photosemiconductor element is encapsulated with a resin layer for encapsulation comprising the cured product of an epoxy resin composition according to claim 1.
